(19) United States
(12) Patent Application Publication
(10) Pub. No.: US 2007/0235836 A1
(43) Pub. Date: Oct. 11, 2007

(54) METHOD OF FORMING A SHALLOW TRENCH ISOLATION STRUCTURE WITH REDUCED LEAKAGE CURRENT IN A SEMICONDUCTOR DEVICE

(75) Inventor: Timothy M. Barry, Colleyville, TX (US)

Correspondence Address: SCHNECK & SCHNECK, P.O. BOX 2-E, SAN JOSE, CA, 95109-0005, US

(73) Assignee: ATMEL CORPORATION, San Jose, CA (US)

(21) Appl. No.: 11/763,716

(22) Filed: Jun. 15, 2007

Related U.S. Application Data
(62) Division of application No. 11/119,176, filed on Apr. 29, 2005.

(51) Int. Cl. H01L 29/00

(52) U.S. Cl. 257/516; 257/E29.001

(57) ABSTRACT

A method for fabricating a shallow trench isolation structure for a subthreshold kink-free semiconductor memory device includes the steps of forming a nitride-oxide-nitride-oxide stack on top of a semiconductor substrate, etching shallow trenches in selected areas and filling them with an insulating material so that it is level with the top nitride layer, removing the top nitride layer, depositing a protective material on top of a first device area, removing the top oxide layer in a second device area, removing the protective material, removing the bottom nitride layer in the second device area, performing an oxide etch to the whole device to remove the top oxide layer in the first device area and the bottom oxide layer in the second device area, removing the bottom nitride layer and the bottom oxide layer in the first device area.

### CROSS-REFERENCE OF RELATED APPLICATION

This is a divisional of pending application Ser. No. 11/119,176 filed Apr. 29, 2005.

### TECHNICAL FIELD

The present invention relates to fabrication methods for semiconductor integrated circuits. More particularly, the present invention relates to fabrication methods for shallow trench isolation structures.

### BACKGROUND ART

In the fabrication of densely packaged integrated circuits, fabricating shallow trench isolation (STI) structures around active devices is a very effective way for preventing carriers from penetrating through the substrate to neighboring devices. A common procedure for the formation of STI structures is shown in FIGS. 1a-1e. In FIG. 1a, a layer of pad oxide 12 and a layer of silicon nitride 14 are sequentially formed on top of a semiconductor substrate 10. In FIG. 1b, shallow trenches are formed by photolithographic masking and anisotropic etching of the overlying layers 12 and 14 and the semiconductor substrate 10. An oxide deposition step that follows fills up the trenches with an oxide material, and a chemical mechanical planarization (CMP) step makes a trench structure 20 level with a top surface of the nitride layer 14. FIG. 1c shows the trench structure 20 left behind once the silicon nitride layer 14 is removed. A subsequent oxide etch shapes the isolation structure 20 as shown in FIG. 1d. A device such as a logic cell or a memory cell may then be form in an active area 18 between two STI structures 20. As shown in FIG. 1e, to form a memory cell, a gate oxide 16 is then formed in the active area 18. A conductive material such as doped polysilicon may then be deposited on top of the gate oxide layer 16 to form a floating gate 22. An oxynitride (ONO) layer 24 may then be deposited on top of the floating gate 22 to form an insulation layer. Another polysilicon layer may then be deposited on top of the ONO layer 24 to form the control gate 26 for the memory cell.

As is well known to those skilled in the art, a memory cell, such as an EEPROM cell, can be programmed or erased more efficiently if its coupling ratio is higher. Coupling ratio is the ratio of a first capacitance (not shown) formed between the control gate 26 and the floating gate 22 and a second capacitance (not shown) formed between the floating gate 22 and the semiconductor substrate 10. Since the first and second capacitances are connected in series, a higher coupling ratio means that, with all other factors remaining the same, there is a higher voltage drop between floating gate 22 and the substrate 10, making it easier and faster for electrons to tunnel through the gate oxide 16. As a result, programming and erasure of the EEPROM cell is quicker.

A variety of ways have been developed over the years to improve the coupling ratio of an EEPROM cell. Two obvious approaches to improve the coupling ratio are either by increasing the first capacitance (between the control gate 26 and the floating gate 22) or by decreasing the second capacitance (between the floating gate 22 and the substrate 10). It is equally well understood that the capacitance can be manipulated either through the manipulation of the capacitive surface area or the manipulation of the distance between the capacitive surfaces. One method for increasing the coupling ratio calls for a thicker gate oxide layer 16 while simultaneously creating a smaller tunneling region in part of the gate oxide layer 16 to facilitate carrier transfer. Another method calls for a reduction in the area occupied by the gate oxide 16. Yet another method calls for thinning the ONO layer 24. It would also be desirable to further increase the first capacitance (between the control gate 26 and the floating gate 22) by increasing the surface area occupied the ONO layer 24. However, with the existing method of forming the isolation trench structure, as described above and illustrated in FIGS. 1a-1e, it is very difficult to expand the ONO area 24 without expanding the gate oxide area 16 at the same time, thereby canceling any advantage of such operation in improving the coupling ratio.

Consequently, it would be desirable to have an isolation trench fabrication scheme that allows for the independent manipulation of the area occupied by the gate oxide layer 16 and the area occupied by the ONO layer 24.

Notice also that the indentations 28 on both sides of an active device area shown in FIG. 1d. These indentations lead to sub-threshold kinks. For a memory cell, as a digital switch, these kinks do not have an effect on its performance. However these kinks in logic devices are highly undesirable as they can cause off-state current leakages, high standby currents, and overall poor performance for the semiconductor device. Therefore, it would also be desirable to have a method that prevents the formation of sub-threshold kinks in the logic device area.

### DISCLOSURE OF THE INVENTION

The present invention is a method for forming a memory circuit with an embedded logic device that provides a high coupling ratio for the memory cells and a kink-free active area for the logic cells. The method includes first forming a first oxide layer, a first masking barrier layer, a second oxide layer and a second masking barrier layer sequentially on a semiconductor substrate. Then, trenches are formed in selected areas and these trenches are filled with a nonconductive material. The second masking barrier layer in both the memory area and the logic cell area are removed followed by the removal of the second oxide layer and the first masking barrier layer in the memory area. The second oxide layer in the logic area is removed along with the first oxide layer in the memory area. Finally, the first masking barrier layer and the first oxide layer in the logic area are removed to complete the formation of the shallow trench isolation structure. By providing an additional oxide layer and an additional nitride layer during the formation of the STI structure, the final shape of the STI structure that is protruded from the substrate can be shaped in such a way that its top area could be substantially smaller than its bottom area, in a way such that the bottom area forms a shoulder for the top area; such a shape enables the making of EEPROM cells with improved coupling ratio. Furthermore, by using intermediate steps to protect the logic device from the over etching of the bottom oxide layer required in the formation of the memory device, the method for forming STI disclosed in the present invention produces logic devices that are free from sub-threshold kinks due to excessive corner and sidewall exposure.

### BRIEF DESCRIPTION OF THE DRAWINGS

FIGS. 1a-1e are a series of cross-sectional views showing conventional methods of forming shallow trench isolation structures.

FIGS. 2a-2h are a series of cross-sectional views showing exemplary embodiments of a method for forming shallow trench isolation structures as disclosed in the present invention.

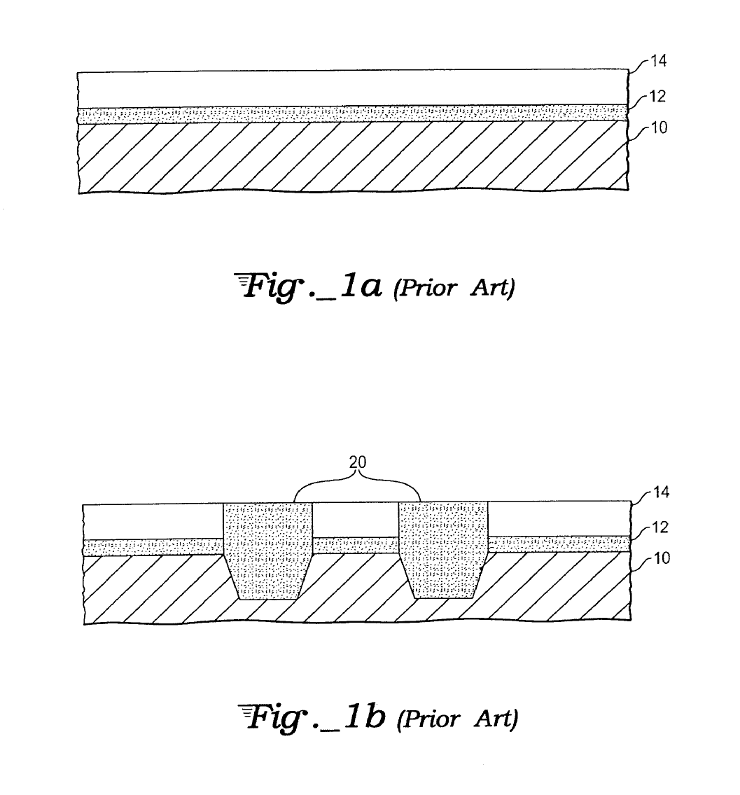

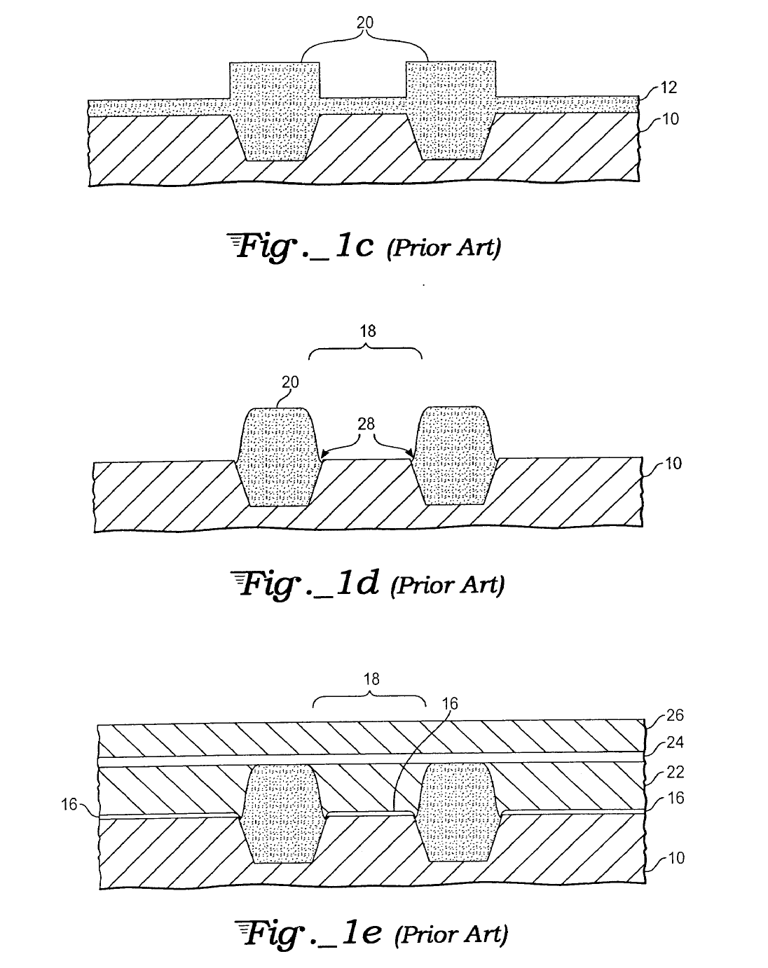

### BEST MODE OF CARRYING OUT THE INVENTION

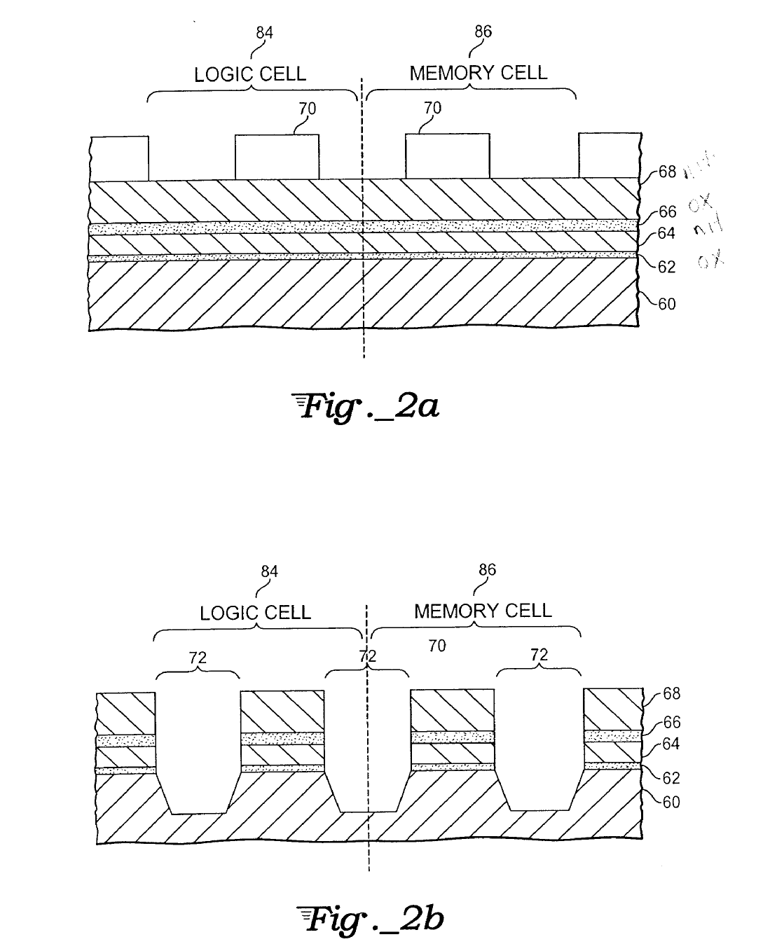

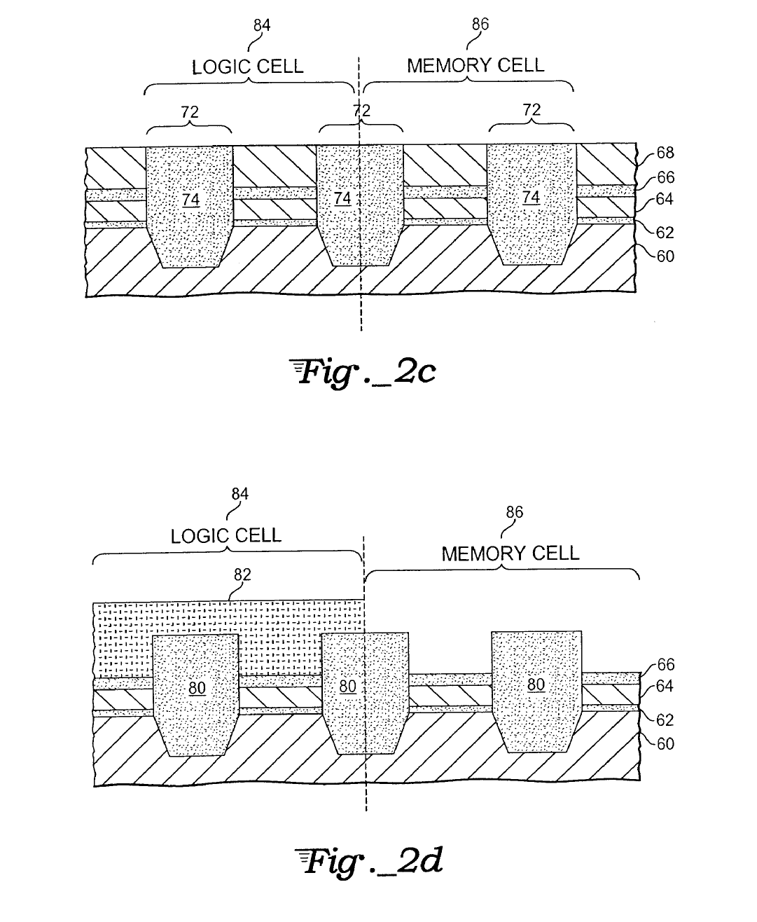

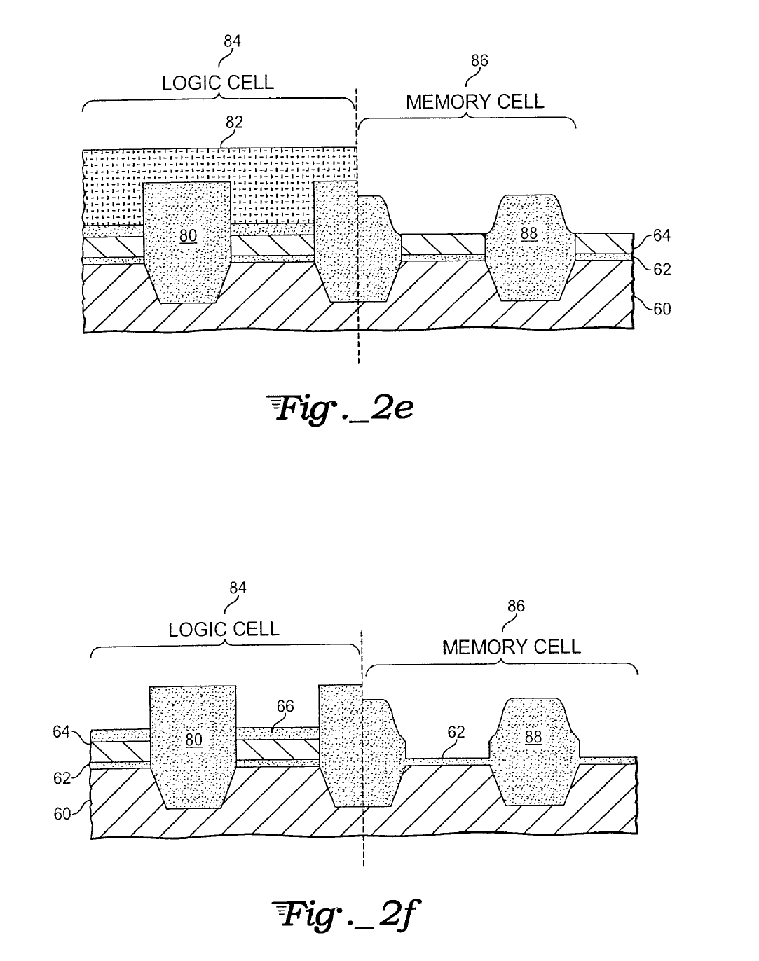

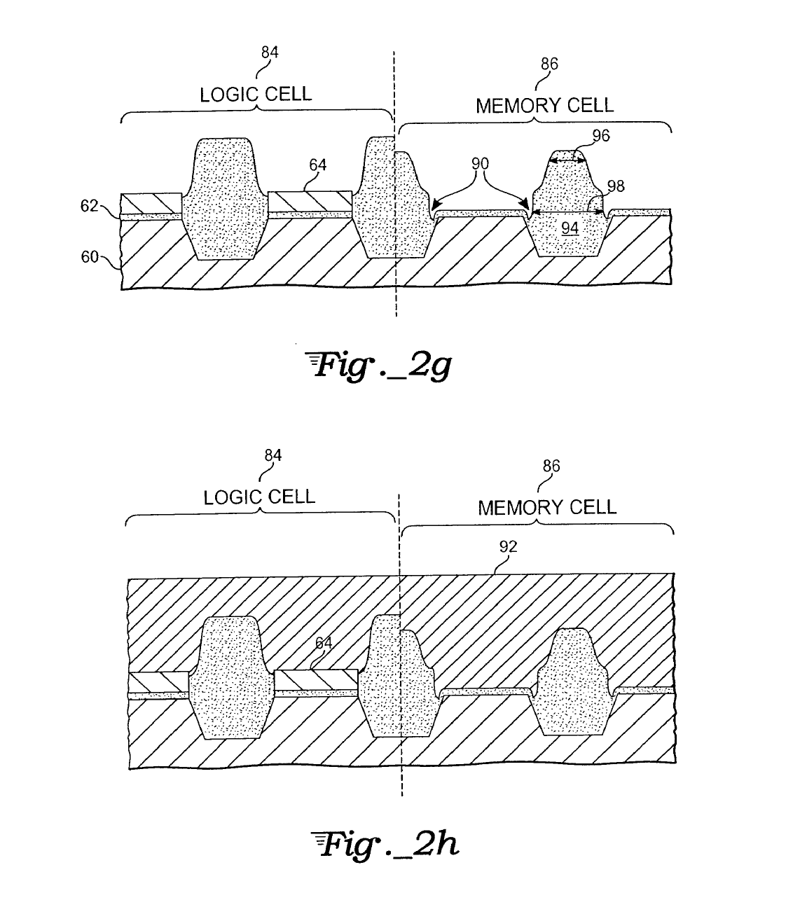

An exemplary embodiment of the present invention is disclosed herein with reference to FIGS. 2a-2h. In the figures, the formation of a logic cell 84 is shown alongside the formation of a memory cell 86. Referring to FIG. 2a, a method of forming a shallow trench isolation structure begins with a blanket thermal oxidation of a silicon substrate 60 to form a thin pad oxide 62 on top of the silicon substrate 60 in both the logic cell area 84 and the memory cell area 86.

Though silicon is used in the exemplary embodiment disclosed below, one skilled in the art will also recognize that other material may be used as well. For example, rather than a silicon substrate, other elemental semiconductors, such as germanium, or semiconductor compounds such as those formed by elements in the group III and the group IV on the periodic table, can be used. In such case, the initial oxide layer may be deposited using CVD, for example, rather than thermally grown.

A first nitride layer 64, which is typically within a thickness range of 100 nm and 500 nm, is then deposited uniformly on top of the pad oxide layer 62, which is typically within a thickness range of 50 nm and 200 nm, followed by a blanket deposition of second silicon dioxide layer 66, which is typically within a thickness range of 100 nm and 300 nm, and a second silicon nitride 68 layer, which is typically within a thickness range of 1000 nm and 2000 nm. As an example, the silicon nitride layers 64 and 68 and the oxide layer 66 may be formed by low-pressure chemical vapor deposition (LPCVD).

In FIG. 2b, trench areas 72 are first defined using etching masks 70, such as a patterned photoresist layer, formed on top of the second silicon nitride 68 layer. Then, anisotropic etching is performed to form the shallow trenches 72.

In FIG. 2c, a dielectric material 74, such as silicon dioxide, is deposited onto the wafer to fill up the trench structure 72. An example of such oxide fill step can be accomplished by LPCVD using tetraethylorthosilicate (TEOS) as a source gas. A densification process is conducted on the trench filling oxide followed by a chemical mechanical planarization (CMP) step that polishes off the layer of excess oxide material, leaving the oxide material in the trench 72 substantially planarized with the second silicon nitride layer 68.

In FIG. 2d, the second nitride layer 68 is stripped, for example, by wet etching using a hot phosphoric acid solution as an etching agent, leaving behind protruding oxide structures 80 in both the logic cell area and the memory cell area. A masking layer 82, such as a photoresist layer, is then formed on top of the logic cell area 84 to protect the logic cell area 84 from subsequent etching steps.

With reference to FIG. 2e, an isotropic oxide etch step, such as a buffered oxide etch (BOE), that follows, exposes the first nitride layer 64 in the memory cell area. The isotropic oxide etch step also sculpts a trench structure 88 in such a way that its top part is narrower than its bottom part.

In FIG. 2f, the masking layer 82 covering the logic cell area 84 and the first nitride layer 64 in the memory area are removed, exposing the second oxide layer 66 in the logic cell area 84 and the pad oxide layer 62 in the memory cell area 86. A blanket oxide etch is then performed to remove the second oxide layer 66 in the logic cell area 84 and the pad oxide layer 62 in the memory cell area 86.

FIG. 2g shows the cross section of the wafer after various oxidation and implantation steps used to define gates of the memory area 86. Notice the shape of the STI structure 94 in the memory area, the top 96 of is the structure is much narrower than the bottom 98. This feature allows the formation of nonvolatile memory cells that have a high coupling ratio. Notice, also, the two indentations 90 on both sides of the active area 96 in the memory cell area 86. Although these features do not affect the performance of memory cells, they can be detrimental to the performance of the logic cells. Protected by the first nitride layer 64, the indentations 90 are prevented from forming in the logic cell area 84.

FIG. 2h shows a conductive layer 92, such as a polysilicon layer, being deposited on top of the wafer. Eventually, the conductive layer 92 covering the logic cell area 84 is removed, while the conductive layer 92 over the memory cell area 86 remains to form the floating gate. Also, the remaining nitride in the logic cell area 84 may be removed by a variety of methods such as in-situ etch during the polysilicon etch, dry etch while etching an interlayer dielectric for the capacitors, or with a stand-alone hot phosphoric etch.

Although the present invention has been described and explained in terms of particular exemplary embodiments, one skilled in the art will realize that additional embodiments can readily be envisioned that are within the scope of the present invention. For instance, although the invention disclosed herein specifies a NONO multi-layer construction methodology, one skilled in the art will quickly recognize that the nitride layers function primarily as a barrier layer to CMP and oxide etch. Therefore, different materials with similar properties to the nitride material could be used as well. Therefore, the scope of the present invention will be limited only by the appended claims.

What is claimed is:

1. A shallow trench isolation structure on a semiconductor substrate comprising:
a bottom section being substantially embedded in the semiconductor substrate;
a middle section; and
a top section, the top and middle sections protruding from the semiconductor substrate, the middle section having a width measurably larger than a top section width, thereby forming a shoulder for the top section.

2. An electronically programmable memory device comprising:
a plurality of shallow trench isolation structures positioned in an uppermost layer of a semiconductor substrate and situated adjacent to one another, each of the plurality of shallow trench isolation structures having a bottom section, a middle section, and a top section;
a first conductive layer disposed between the bottom sections of adjacent shallow trench isolation structures and above a first isolation layer, the first isolation layer produced on top of the uppermost layer of the semiconductor substrate;
a second conductive layer disposed between the top sections of adjacent shallow trench isolation structures and above a second isolation layer, the second isolation layer produced above the first conductive layer;
a first capacitor being formed by the second conductive layer and the first conductive layer, the second and first conductive layers substantially parallel to one another and separated by the second isolation layer; and
a second capacitor being formed by the first conductive layer and the uppermost layer of the semiconductor substrate, the first conductive layer and the uppermost layer of the semiconductor substrate substantially parallel to one another and separated by the first isolation layer.

3. The device of claim 2, wherein each of the bottom sections of the plurality of adjacent trench isolation structures being substantially embedded in the semiconductor substrate and each of the uppermost and middle sections of the plurality of adjacent trench isolation structures protruding from the semiconductor substrate, each of the middle sections having a width measurably larger than the width of the related top section, thereby forming a shoulder for each top section.

4. The device of claim 3, wherein each of the plurality of shallow trench isolation structures being narrower laterally at the top section than at the base forming a difference in width along a vertical axis of the isolation structures, the difference in width producing a greater spacing between adjacent shallow trench isolation structures at the top sections than at the bottom sections.

5. The device of claim 3, wherein the second conductive layer and the second isolation layer are wider than the first conductive layer and the first isolation layer, the increased width of the second conductive layer and the second isolation layer produced by the shoulders of each of the plurality of adjacent trench isolation structures.

6. The device of claim 3, wherein a capacitive magnitude of the first capacitor being greater than a capacitive magnitude of the second capacitor, the greater capacitive magnitude of the first capacitor produced by the shoulders of each of the plurality of adjacent trench isolation structures.

7. The device of claim 3, wherein a capacitive magnitude of the first capacitor being greater than a capacitive magnitude of the second capacitor produces an increased coupling ratio.

8. The device of claim 3, wherein a capacitive magnitude of the first capacitor is produced independent of a capacitive magnitude of the second capacitor.

9. A semiconductor logic device comprising:
a plurality of shallow trench isolation structures positioned in an uppermost layer of a semiconductor substrate and situated adjacent to one another, each of the plurality of shallow trench isolation structures having a bottom section, a middle section, and a top section;
a first isolation layer disposed between the bottom sections of the plurality of adjacent shallow trench isolation structures, the first isolation layer further disposed on top of the uppermost layer of the semiconductor substrate, each abutment of an edge of the first isolation layer with an edge of one of the plurality of adjacent shallow trench isolation structures being continuous;
a first conductive layer disposed between a further portion of the bottom sections of the plurality of adjacent shallow trench isolation structures, the continuous abutment of the first isolation layer with the plurality of adjacent shallow trench isolation structures producing a continuous isolation of electrical current from between the first conductive layer and the uppermost layer of the semiconductor substrate;
a plurality of diffused dopant regions within an uppermost portion of the upper surface layer of the semiconductor substrate; and
at least one gate region being formed from a portion of the first conductive layer disposed between at least two adjacent diffused dopant regions, the gate region capable of producing an electrically conductive channel between two adjacent diffused dopant regions.

10. The device of claim 9 wherein each of the bottom sections of the plurality of adjacent trench isolation structures being substantially embedded in the semiconductor substrate and each of the uppermost and middle sections of the plurality of adjacent trench isolation structures protruding from the semiconductor substrate, each of the middle sections having a width measurably larger than the width of the related top section, thereby forming a shoulder for each top section.

11. The device of claim 10, wherein each of the plurality of shallow trench isolation structures being narrower laterally at the top section than at the base section thus forming a difference in width along a vertical axis of the isolation structures, the difference in width producing a greater spacing between adjacent shallow trench isolation structures at the top sections than at the bottom sections.

12. A semiconductor logic cell comprising:
a plurality of shallow trench isolation structures positioned in an uppermost layer of a semiconductor substrate and situated adjacent to one another, each of the plurality of shallow trench isolation structures having a bottom section, a middle section, and a top section;
a first isolation layer produced on top of the uppermost layer of the semiconductor substrate;
a first conductive layer disposed between the bottom sections of the plurality of adjacent shallow trench isolation structures and above the first isolation layer;
a plurality of diffused dopant regions within an uppermost portion of the upper surface layer of the semiconductor substrate;
at least one gate region being formed from a portion of the first conductive layer disposed between at least two adjacent diffused dopant regions, the gate region capable of producing an electrically conductive channel between two adjacent diffused dopant regions;
at least one logic device being the confluence of the plurality of diffused dopant regions and the at least one gate region;
a second isolation layer produced above at least one portion of the first conductive layer;
a second conductive layer disposed between the top sections of the plurality of adjacent shallow trench isolation structures and above the second isolation layer; and
at least one electronically programmable memory device being the first isolation layer, the first conductive layer, the second isolation layer, and the second conductive layer in a vertical stack.

13. The device of claim 12, further comprising:
a first capacitor being formed where the second conductive layer being produced topologically coincident with the first conductive layer, the second and first conductive layers substantially parallel to one another and separated by the second isolation layer and a second capacitor being formed by the first conductive layer and the uppermost layer of the semiconductor substrate, the first conductive layer and the uppermost layer of the semiconductor substrate substantially parallel to one another and separated by the first isolation layer.

14. The device of claim 13, wherein each of the bottom sections of the plurality of adjacent trench isolation structures being substantially embedded in the semiconductor substrate and each of the uppermost and middle sections of the plurality of adjacent trench isolation structures protruding from the semiconductor substrate, each of the middle sections having a width measurably larger than the width of the related top section, thereby forming a shoulder for each top section.

15. The device of claim 14, wherein each of the plurality of shallow trench isolation structures being narrower laterally at the top section than at the base forming a difference in width along a vertical axis of the isolation structures, the difference in width producing a greater spacing between adjacent shallow trench isolation structures at the top sections than at the bottom sections.

16. The device of claim 14, wherein the second conductive layer and the second isolation layer are wider than the first conductive layer and the first isolation layer, the increased width of the second conductive layer and the second isolation layer produced by the shoulders of each of the plurality of adjacent trench isolation structures.

17. The device of claim 14, wherein a capacitive magnitude of the first capacitor being greater than a capacitive magnitude of the second capacitor, the greater capacitive magnitude of the first capacitor produced by the shoulders of each of the plurality of adjacent trench isolation structures.

18. The device of claim 14, wherein a capacitive magnitude of the first capacitor being greater than a capacitive magnitude of the second capacitor produces an increased coupling ratio.

19. The device of claim 14, wherein a capacitive magnitude of the first capacitor is produced independent of a capacitive magnitude of the second capacitor.
